(19) United States
(12) Patent Application Publication
(10) Pub. No.: US 2016/0090664 A1
(43) Pub. Date: Mar. 31, 2016

(54) METHOD FOR PRODUCING SIC SINGLE CRYSTAL

(71) Applicant: TOYOTA JIDOSHA KABUSHIKI KAISHA, Toyota-shi (JP)

(72) Inventors: Katsunori DANNO, Susono-shi (JP); Hironori DAIKOKU, Susono-shi (JP); Masayoshi DOI, Nagoya-shi (JP); Kazuhiko KUSUNOKI, Nishinomiya-shi (JP)

(21) Appl. No.: 14/854,517

(22) Filed: Sep. 15, 2015

(30) Foreign Application Priority Data
Sep. 25, 2014 (JP) 2014-195723

(51) Int. Cl. C30B 19/06; C30B 19/08; C30B 29/36; C30B 19/04

(52) U.S. Cl. CPC C30B 19/067; C30B 19/04; C30B 19/062; C30B 19/08; C30B 29/36

(57) ABSTRACT

A method for producing a SiC single crystal by a solution process, comprising contacting a seed crystal substrate held on a seed crystal holding shaft with a Si—C solution to conduct crystal growth of a SiC single crystal, the Si—C solution being housed in a crucible and having a temperature gradient in which the temperature decreases from the interior toward the surface,
wherein a high-frequency coil is disposed around the side sections of the crucible, and
the crucible has a multilayer structure including an inner crucible, and one or more outer crucibles disposed surrounding the inner crucible, and
wherein the method comprises moving the inner crucible alone in the vertical upward direction so as to minimize changes in the relative position of the liquid level of the Si—C solution and the center section of the high-frequency coil in the vertical direction during the crystal growth of the SiC single crystal.

### TECHNICAL FIELD

The present disclosure relates to a method for producing a SiC single crystal by a solution process.

### BACKGROUND ART

SiC single crystals are thermally and chemically very stable, superior in mechanical strengths, and resistant to radiation, and also have superior physical properties, such as high breakdown voltage and high thermal conductivity compared to Si single crystals. They are therefore able to exhibit high output, high frequency, voltage resistance and environmental resistance that cannot be realized with existing semiconductor materials, such as Si single crystals and GaAs single crystals, and are considered ever more promising as next-generation semiconductor materials for a wide range of applications including power device materials that allow high power control and energy saving to be achieved, device materials for high-speed large volume information communication, high-temperature device materials for vehicles, radiation-resistant device materials and the like.

Typical growth processes for growing SiC single crystals that are known in the prior art include gas phase processes, the Acheson process and solution processes. Among gas phase processes, for example, sublimation processes have a drawback in that grown single crystals have been prone to hollow penetrating defects known as “micropipe defects”, lattice defects, such as stacking faults, and generation of polymorphic crystals. However, most SiC bulk single crystals are conventionally produced by sublimation processes. In the Acheson process, heating is carried out in an electric furnace using silica stone and coke as starting materials, and therefore it has not been possible to obtain single crystals with high crystallinity due to impurities in the starting materials.

Solution processes are processes in which molten Si or a molten liquid comprising another metal added to Si is formed in a graphite crucible and C is dissolved into the molten Si or molten liquid, and a SiC crystal layer is deposited and grown on a seed crystal substrate set in the low temperature section. The C-dissolved molten liquid (Si—C solution) situated in the graphite crucible is heated with a high-frequency coil situated surrounding the graphite crucible (PTL 1).

### CITATION LIST

### Patent Literature

### [PTL 1] Japanese Unexamined Patent Publication No. 2009-167044

### [PTL 2] Japanese Unexamined Patent Publication No. 2014-19614

### SUMMARY OF THE INVENTION

### Problems to be Solved by the Invention

In solution processes, crystal growth takes place in a state of near thermal equilibrium compared to gas phase processes, such that low defects may be expected, and therefore methods for producing SiC single crystals by solution processes have been proposed as mentioned above. However, it is still not possible in many cases to accomplish homogeneous crystal growth due to generation of inclusions in the SiC crystal during growth of the SiC single crystal. Hence, there is a desire for a method for producing a SiC single crystal that allows homogeneous crystal growth by minimizing generation of inclusions compared to the prior art.

### Means for Solving the Problems

One embodiment of the present disclosure is a method for producing a SiC single crystal by a solution process, comprising contacting a seed crystal substrate held on a seed crystal holding shaft with a Si—C solution to conduct crystal growth of a SiC single crystal, the Si—C solution being housed in a crucible and having a temperature gradient in which the temperature decreases from the interior toward the surface,

wherein a high-frequency coil is disposed around the side sections of the crucible, and

the crucible has a multilayer structure including an inner crucible, and one or more outer crucibles disposed surrounding the inner crucible, and

wherein the method comprises moving the inner crucible alone in the vertical upward direction so as to minimize changes in the relative position of the liquid level of the Si—C solution and the center section of the high-frequency coil in the vertical direction during the crystal growth of the SiC single crystal.

### Effect of the Invention

According to one embodiment of the present disclosure, it is possible to obtain a SiC single crystal with more homogeneous crystal growth by reducing generation of inclusions, compared to the prior art.

### BRIEF DESCRIPTION OF THE DRAWINGS

FIG. 1 is a cross-sectional schematic drawing of an example of a single crystal production apparatus based on a solution process, to be used for one embodiment of the present disclosure.

FIG. 2 is a cross-sectional schematic drawing representing an example of a single crystal production apparatus based on a solution process used in the prior art.

FIG. 3 is a cross-sectional schematic drawing of a SiC single crystal ingot having a concave crystal growth plane.

FIG. 4 is a pair of schematic diagrams showing the locations where a grown crystal is cut when examining the presence of inclusions in the grown crystal.

FIG. 5 is a cross-sectional schematic drawing of the meniscus formed between a seed crystal substrate and a Si—C solution.

FIG. 6 is a cross-sectional schematic drawing of a seed crystal holding shaft having a constitution such that the thermal conductivity of the center section is smaller than the thermal conductivity of the side section.

FIG. 7 is a cross-sectional schematic drawing of a seed crystal holding shaft wherein a heat-insulating material is disposed in the hollow part of the center section.

FIG. 8 is a cross-sectional schematic drawing showing a constitution of a single crystal production apparatus at the start of crystal growth.

FIG. 9 is a cross-sectional schematic drawing showing a constitution of a single crystal production apparatus during crystal growth, where the entire hot zone has been moved, in a reference example.

FIG. 10 is a cross-sectional schematic drawing showing a constitution of a single crystal production apparatus during crystal growth, where only the inner crucible has been moved, in an example.

FIG. 11 is a cross-sectional schematic drawing showing a constitution of a single crystal production apparatus during crystal growth, in a comparative example.

FIG. 12 shows the results of a simulation of the state of flow of a Si—C solution, directly under the crystal growth plane at the start of crystal growth (initial settings).

FIG. 13 shows the results of a simulation of the state of flow of a Si—C solution directly under the crystal growth plane, where the inner crucible alone has been moved, in an example.

FIG. 14 shows the results of a simulation of the state of flow of a Si—C solution directly under the crystal growth plane, where the entire hot zone has been moved, in a reference example.

FIG. 15 shows the results of a simulation of the state of flow of a Si—C solution directly under the crystal growth plane, in a comparative example.

### DESCRIPTION OF EMBODIMENTS

Throughout the present specification, the indication “-1” in an expression, such as “(000-1) face”, is used where normally a transverse line is placed over the numeral.

The present inventors have conducted diligent research on methods of achieving more homogeneous crystal growth of SiC single crystals by minimizing generation of inclusions compared to the prior art, and have found that the position of the liquid level of the Si—C solution in the vertical direction tends to vary when a SiC single crystal is being grown, and that when the relative position of the liquid level of the Si—C solution and the center section of the high-frequency coil changes, the state of flow and the temperature gradient of the Si—C solution are altered, thus resulting in generation of inclusions and making it impossible to perform homogeneous crystal growth.

One embodiment of the present disclosure has been obtained based on this knowledge, and it is a method for producing a SiC single crystal by a solution process, comprising contacting a seed crystal substrate held on a seed crystal holding shaft with a Si—C solution to conduct crystal growth of a SiC single crystal, the Si—C solution being housed in a crucible and having a temperature gradient in which the temperature decreases from the interior toward the surface, wherein a high-frequency coil is disposed around the side sections of the crucible, and the crucible has a multilayer structure including an inner crucible, and one or more outer crucibles disposed surrounding the inner crucible, and wherein the method comprises moving the inner crucible alone in the vertical upward direction so as to minimize changes in the relative position of the liquid level of the Si—C solution and the center section of the high-frequency coil in the vertical direction during the growth of the SiC single crystal.

According to this embodiment of the present disclosure, it is possible to reduce changes in the state of flow and temperature gradient of the Si—C solution compared to the prior art, and therefore generation of inclusions can be reduced to allow more homogeneous crystal growth than by the prior art.

Inclusions are generated by incorporating the Si—C solution used for SiC single crystal growth in the grown crystal. Inclusions constitute macrodefects for a single crystal, and such defects are unacceptable for device materials. When inclusions are generated in a grown crystal, solvent components, such as Cr that may be present in the solvent used as the Si—C solution, may be detected as the inclusions.

A solution process is a process for producing a SiC single crystal in which a SiC seed crystal is contacted with a Si—C solution having a temperature gradient such that the temperature decreases from the interior toward the surface, to grow a SiC single crystal. By forming a temperature gradient in which the temperature decreases from the interior of the Si—C solution toward the surface of the Si—C solution, the surface region of the Si—C solution becomes supersaturated and a SiC single crystal is grown from the seed crystal substrate contacting with the Si—C solution.

For the purpose of the present application, the state of flow of the Si—C solution may be represented as the speed of upward flow of the Si—C solution from the depth of the Si—C solution toward the crystal growth plane.

Flow of the Si—C solution comprises upward flow of the Si—C solution from the depth of the Si—C solution toward the crystal growth plane, flow of the Si—C solution from the center section directly under the crystal growth plane toward the outer peripheral section of the crystal growth plane, and flow of the Si—C solution from the outer peripheral section toward the depth, wherein the Si—C solution flows in manner circulating inside the crucible. The flow of the Si—C solution is created by electromagnetic stirring with a high-frequency coil, rotation of a seed crystal substrate contacting a Si—C solution, rotation of a crucible, or the like.

In this circulation of the Si—C solution inside the crucible, the flow of the Si—C solution, which is in direct contact with the crystal growth plane, from the depth of the Si—C solution toward the crystal growth plane and the flow of the Si—C solution from the center section directly below the crystal growth plane toward the outer peripheral section of the crystal growth plane, have major influences on the crystallinity of the grown SiC single crystal. Since the state of flow of the Si—C solution from the center section directly below the crystal growth plane toward the outer peripheral section of the crystal growth plane is determined by the state of flow of the Si—C solution from the depth of the Si—C solution toward the crystal growth plane, maintaining a constant speed for the upward flow of the Si—C solution from the depth of the Si—C solution toward the crystal growth plane is effective for minimizing generation of inclusions to achieve homogeneous crystal growth.

The crystal growth plane is the downward facing plane of the seed crystal substrate contacting with the Si—C solution prior to crystal growth, while during crystal growth it is the downward facing plane of the grown crystal contacting with the Si—C solution. The term “directly below the crystal growth plane” means directly below the growth surface of the seed crystal substrate prior to crystal growth, while during crystal growth it means directly below the growth surface of the grown crystal, and refers to a location in a range of preferably 0 to 10 mm vertically downward from the crystal growth plane contacting with the Si—C solution.

The liquid level of the Si—C solution may fall during growth of the SiC single crystal. While it is not our intention to be limited to any particular theory, the reason for the fall in liquid level of the Si—C solution may be mainly due to the fact that components, such as carbon, elute from the crucible into the Si—C solution, thus increasing the internal volume of the crucible, that components of the Si—C solution evaporate from the liquid level of the Si—C solution, and that components of the Si—C solution are converted to the grown crystal.

When the liquid level of the Si—C solution falls during growth of the SiC single crystal, the relative position of the liquid level of the Si—C solution with respect to the center section of the high-frequency coil in the vertical direction changes from the start of SiC single crystal growth, i.e. the initial setting. When the relative position between the liquid level of the Si—C solution and the center section of the high-frequency coil in the vertical direction changes, the flow speed and the temperature gradient of the Si—C solution directly below the crystal growth plane are altered.

According to one embodiment of the present disclosure, the inner crucible alone is moved in the vertical upward direction so as to minimize changes in the relative position of the liquid level of the Si—C solution and the center section of the high-frequency coil in the vertical direction during growth of the SiC single crystal, and this can reduce alterations in the state of flow and temperature gradient of the Si—C solution compared to the prior art, to minimize generation of inclusions and achieve more homogeneous crystal growth, compared to the prior art.

The center section of the high-frequency coil may be a predetermined location of the high-frequency coil in the vertical direction, which is disposed in the vertical direction, at the start of crystal growth with the initial settings, and it is not necessarily limited to the “center section” in the strict sense. For example, the center section of the high-frequency coil may be any location at the start of crystal growth with the initial settings, such as the center location between the top end and bottom end of the high-frequency coil disposed in the vertical direction, or the location in the vertical direction that is maximally heated when a body to be heated, such as a carbon material, is situated adjacent to the high-frequency coil, or, when the high-frequency coil is composed of multiple levels of coils, such as an upper level coil and a lower level coil, the location at the border between the upper level coil and the lower level coil.

At the start of growth of the SiC single crystal, the center section of the high-frequency coil may be the same location as the liquid level of the Si—C solution, a higher location than the liquid level of the Si—C solution, or a lower location than the liquid level of the Si—C solution.

The inner crucible is moved so that shifting in the relative positions of the liquid level of the Si—C solution and the initially set center section of the high-frequency coil in the vertical direction is preferably within 1 mm, more preferably within 0.5 mm even more preferably within 0.1 mm, and yet more preferably substantially 0 mm. If the shift in relative positions is within the aforementioned range, it will be possible to further reduce changes in the speed of upward flow and the temperature gradient of the Si—C solution.

For the purpose of the present application, the term “vertical direction” is the direction perpendicular to the liquid level of the Si—C solution, and so long as the object of the invention can be achieved, it is naturally not limited to the vertical direction in the strictest sense and may include directions that are substantially perpendicular to the liquid level of the Si—C solution.

In regard to the timing for moving the inner crucible, the relationship between the growth time during growth of the SiC single crystal and variation in the location of the liquid level of the Si—C solution may be measured beforehand and the inner crucible may be moved according to a preset program, or the inner crucible may be moved while monitoring the location of the liquid level of the Si—C solution so as to keep the shift in relative position within the range specified above as the preferred range, for example, a relative position shift of within 1 mm, or so as to substantially prevent any shift in relative position.

The change in speed of the upward flow of the Si—C solution is preferably within ±30%, more preferably within ±20% and even more preferably within ±11%, based on the upward speed of the Si—C solution as initially set:

The change in temperature gradient of the Si—C solution is preferably less than ±20% and more preferably within ±15%, based on the temperature gradient of the Si—C solution as initially set.

The upward speed and temperature gradient of the Si—C solution as initially set are the upward speed and temperature gradient when the Si—C solution has reached a stable state at the start of crystal growth, or in other words, the upward speed and temperature gradient of the Si—C solution when it has reached a stable state before any substantial change in liquid level height of the Si—C solution.

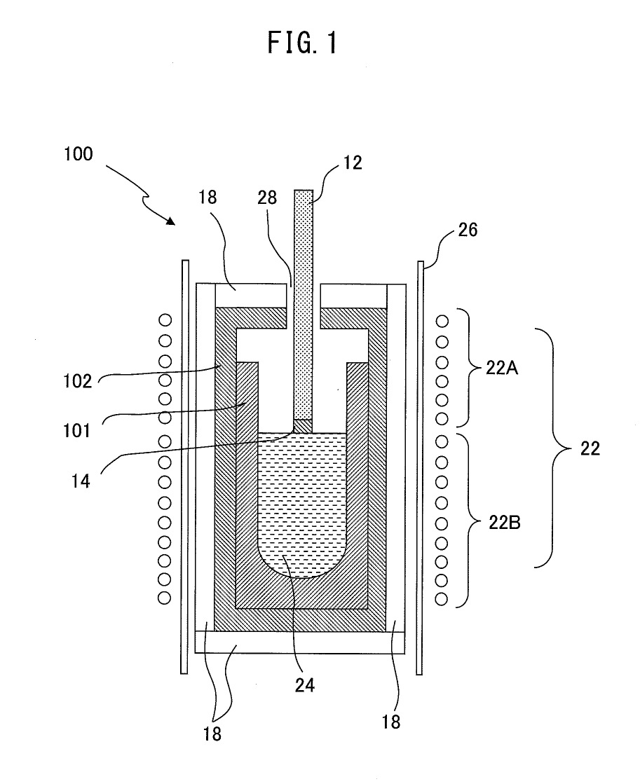

FIG. 1 is a cross-sectional schematic drawing of an example of a SiC single crystal production apparatus, that may be used for an embodiment of the present disclosure. The SiC single crystal production apparatus 100 of FIG. 1 comprises a crucible having a multilayer structure that comprises an inner crucible 101 and one or more outer crucibles 102 disposed surrounding the inner crucible 101.

The SiC single crystal production apparatus 100 comprises an inner crucible 101 housing a Si—C solution 24, formed by dissolution of C in a molten liquid of Si or Si/X. A temperature gradient is formed in the inner crucible 101 in which the temperature is decreased from the interior of the Si—C solution 24 toward the surface of the Si—C solution 24, and the seed crystal substrate 14 that is held at the tip of the vertically movable seed crystal holding shaft 12 is contacted with the Si—C solution 24 to allow growth of the SiC single crystal from the seed crystal substrate 14.

The Si—C solution 24 is prepared by loading the starting materials into the inner crucible 101, melting them by heating to prepare Si or Si/X molten liquid, and dissolving C therein. X is one or more metals other than Si, and is not particularly restricted so long as it can form a liquid phase (solution) that is in a state of thermodynamic equilibrium with SiC (solid phase). Suitable examples of X metals include Ti, Mn, Cr, Ni, Ce, Co, V and Fe. For example, Cr and the like may be loaded in the inner crucible 101 in addition to Si to form a Si—Cr solution or the like.

The inner crucible 101 and the outer crucible 102 may be carbonaceous crucibles, such as graphite crucibles, or SiC crucibles. Dissolution of the C-containing inner crucible 101 causes C to dissolve into the molten liquid, allowing formation of a Si—C solution. This can avoid the presence of undissolved C in the Si—C solution 24, and prevent waste of SiC by deposition of the SiC single crystal onto the undissolved C. The supply of C may be carried out by utilizing a method of, for example, blowing in hydrocarbon gas or loading a solid C source together with the molten liquid starting material, or these methods may be combined together with dissolution of the crucible.

By moving the inner crucible 101 alone in the vertical upward direction, without moving the high-frequency coil 22, outer crucible 102 and heat-insulating material 18 (when a heat-insulating material is present), it is possible to maintain the positional relationship between the heated section (also referred to as “hot zone”) including the outer crucible 102 and the heat-insulating material 18 (when a heat-insulating material is present), and the center section of the high-frequency coil 22, such that in addition to minimizing changes in the flow speed of the Si—C solution 24 directly below the crystal growth plane, it is possible to also minimize changes in the temperature gradient of the Si—C solution directly below the crystal growth plane. This allows generation of inclusions to be reduced in a stable manner, allowing homogeneous crystal growth to be accomplished.

When a carbonaceous crucible, such as a graphite crucible, or a SiC crucible, is heated with a high-frequency coil situated surrounding the side sections, a high-frequency inductive current flows preferentially in an outer peripheral section of the crucible to heat the outer peripheral section, and the interior Si—C solution is heated. On the other hand, since a portion of the electromagnetic field from the high-frequency coil reaches the Si—C solution, the Lorentz force caused by the high-frequency heating is applied to the Si—C solution inside the graphite crucible, producing an effect of stirring the Si—C solution.

In order for the stirring effect by the high-frequency coil to adequately reach the Si—C solution, the thickness of the side sections of the outer crucible 102 and the thickness of the side sections of the inner crucible 101 are preferably each in the range of 5 to 10 mm. The outer crucible 102 may be composed of two or more crucibles. When the outer crucible 102 is composed of multiple crucibles, the thickness of the outer crucible 102 will be the total thickness of all of the outer crucibles.

The seed crystal holding shaft 12 may be a graphite shaft that holds the seed crystal substrate on one end face. A commonly used graphite shaft may be used as the seed crystal holding shaft for an embodiment of the present disclosure. The seed crystal holding shaft 12 may have any desired shape, such as cylindrical or columnar, and there may be used a graphite shaft having the same end face shape as the top face of the seed crystal substrate 14.

Holding of the seed crystal substrate 14 on the seed crystal holding shaft 12 may be carried out by holding the top face of the seed crystal substrate 14 on the tip of the seed crystal holding shaft 12 by using an adhesive or the like.

The Si—C solution 24 preferably has a surface temperature of 1800° C. to 2200° C., which will minimize fluctuation in the amount of dissolution of C into the Si—C solution.

Temperature measurement of the Si—C solution 24 can be carried out by using a thermocouple or radiation thermometer. From the viewpoint of high temperature measurement and preventing inclusion of impurities, the thermocouple is preferably a thermocouple comprising a tungsten-rhenium wire covered with zirconia or magnesia glass, placed inside a graphite protection tube.

For thermal insulation, the periphery of the outer crucible 102 is preferably covered with a heat-insulating material 18. These may be housed together inside a quartz tube 26. As shown in FIG. 1, a heating high-frequency coil 22 is disposed around the side sections of the outer crucible 102, or when a quartz tube 26 is used, around the side sections of the outer crucible 102 sandwiching the quartz tube 26. The high-frequency coil 22 may have a multilevel structure, and for example, it may be configured with an upper level coil 22A and a lower level coil 22B. The upper level coil 22A and lower level coil 22B each have independently controllable outputs.

The heat-insulating material 18 used may be a graphite-based heat-insulating material, carbon fiber-molded heat-insulating material, or anisotropic heat-insulating material, such as pyrolytic graphite (PG).

Since the temperature of the inner crucible 101, outer crucible 102, heat-insulating material 18, quartz tube 26 and high-frequency coil 22 will be high, they are preferably situated inside a water-cooling chamber. The water-cooling chamber is preferably provided with a gas inlet and a gas exhaust vent to allow atmospheric modification in the apparatus.

The inner crucible 101, outer crucible 102 and heat-insulating material 18 (when a heat-insulating material 18 is used) may be provided with an opening 28 at the top, through which the seed crystal holding shaft 12 passes. In the single crystal production apparatus 100 shown in FIG. 1, the entire top of the inner crucible 101 is open, and the outer crucible 102 and heat-insulating material 18 have openings that are narrower than the top of the inner crucible 101. By adjusting the gap (spacing) between the inner crucible 101, outer crucible 102 and heat-insulating material 18 and the seed crystal holding shaft 12 at the opening 28, it is possible to vary the amount of radiation heat loss from the surface of the Si—C solution 24. Although it is usually necessary to keep the interiors of the inner crucible 101 and outer crucible 102 at high temperature, setting a large gap between the inner crucible 101, outer crucible 102 and heat-insulating material 18 and the seed crystal holding shaft 12 at the opening 28 can increase radiation heat loss from the surface of the Si—C solution 24, while setting a small gap between the inner crucible 101, outer crucible 102 and heat-insulating material 18 and the seed crystal holding shaft 12 at the opening 28 can reduce radiation heat loss from the surface of the Si—C solution 24. The gap between the inner crucible 101 and the seed crystal holding shaft 12, the gap between the outer crucible 102 and the seed crystal holding shaft 12 and the gap between the heat-insulating material 18 and the seed crystal holding shaft 12 at the opening 28 may be the same or different. When a meniscus has formed, as described below, radiation heat loss can take place from the meniscus portion as well.

The temperature of the Si—C solution 24 usually has a temperature distribution with a lower temperature at the surface than the interior of the Si—C solution 24 due to radiation and the like. Further, a temperature gradient can be formed in the Si—C solution 24 in the direction perpendicular to the surface of the Si—C solution 14 so that an upper portion of the solution contacting the seed crystal substrate 24 is at low temperature and a lower portion of the solution (the interior) is at high temperature, by adjusting the number of coils and spacing of the high-frequency coil 22, the positional relationship of the high-frequency coil 22 and the inner crucible 101 in the height direction, and the output of the high-frequency coil 22. For example, the output of the upper level coil 22A may be smaller than the output of the lower level coil 22B, to form a temperature gradient in the Si—C solution 24 in which an upper portion of the solution is at low temperature and a lower portion of the solution is at high temperature. The temperature gradient is preferably 10 to 50° C./cm in a range of from, for example, the solution surface to a depth of about 10 mm.

The C that has dissolved in the Si—C solution 24 is dispersed by flow of the Si—C solution. In the Si—C solution near the bottom face of the seed crystal substrate 14, a temperature gradient can be formed so that it is at lower temperature than the interior of the Si—C solution 24, due to control of output from the high-frequency coil 22 as the heating device, heat radiation from the surface of the Si—C solution 24 and heat loss through the seed crystal holding shaft 12. When the C that has dissolved into the solution interior that is at high temperature and has high solubility reaches the region near the seed crystal substrate that is at low temperature and has low solubility, a supersaturated state appears and a SiC single crystal is grown on the seed crystal substrate 14 by virtue of supersaturation as a driving force.

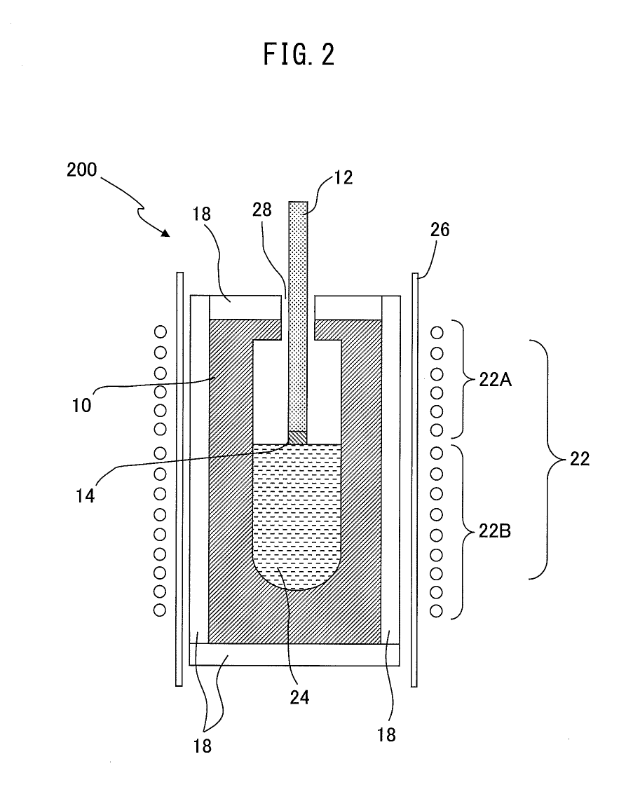

FIG. 2 shows an example of a SiC single crystal production apparatus used in the prior art. The SiC single crystal production apparatus 200 of FIG. 2 comprises a crucible 10. The rest of the constitution is the same as the SiC single crystal production apparatus 100 of FIG. 1, and it may also have a heat-insulating material 18.

In the SiC single crystal production apparatus 200 of FIG. 2, when the position of the liquid level of the Si—C solution changes during growth of the SiC single crystal, the relative position of the liquid level of the Si—C solution and the center section of the high-frequency coil in the vertical direction may be controlled either by moving the crucible 10 in the vertical upward direction, or when the periphery of the crucible 10 is covered by a heat-insulating material 18, by moving the heat-insulating material 18 covering the crucible 10 together with the crucible 10 in the vertical upward direction. However, when the entire heated section (also referred to as hot zone) including the crucible and heat-insulating material (when a heat-insulating material is present) is moved, it is difficult to reduce variation in the temperature gradient of the Si—C solution.

According to one embodiment of the present disclosure, the SiC single crystal is preferably grown so as to have a concave crystal growth plane. By performing crystal growth in a solution process so as to have a concave crystal growth plane, it is possible to further prevent generation of inclusions across the entire thickness direction or diameter direction, as desired.

The SiC grown single crystal having a concave crystal growth plane preferably has a portion of the center section substantially parallel to the just plane of crystal growth, and has a concave crystal growth plane whose slope increases toward the outer peripheral section of the growth surface. The maximum angle θ of the slope of the concave crystal growth plane with respect to the just plane of crystal growth is preferably in the range of 0<θ≦8°, more preferably in the range of 1≦θ≦8°, even more preferably in the range of 2≦θ≦8° and yet more preferably in the range of 4≦θ≦8°. If the maximum angle θ of the slope of the concave crystal growth plane is within the aforementioned range, it will be even easier to minimize generation of inclusions.

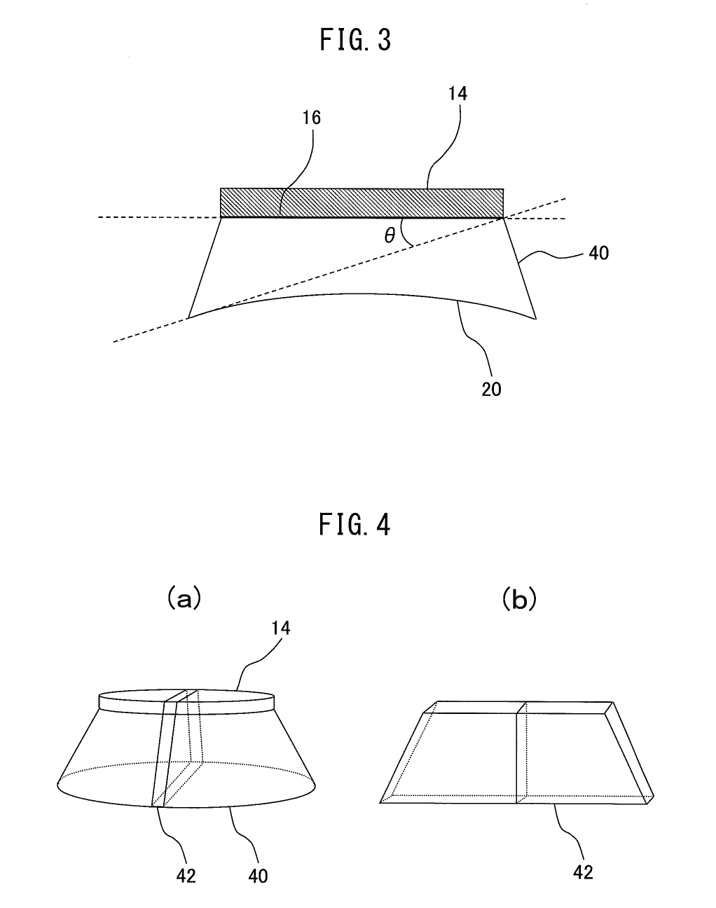

The maximum angle θ of the slope can be measured by any desired method. For example, when a SiC single crystal with a concave crystal growth plane 20 is grown by using a seed crystal substrate 14 having a just plane 16, as shown in FIG. 3, it is possible to measure the maximum angle θ as the slope of the tangent line on the outermost periphery of the concave crystal growth plane 20 with respect to the just plane 16 of the seed crystal substrate 14.

The growth surface of the SiC single crystal having a concave crystal growth plane may be the (0001) face (also referred to as the Si-face) or the (000-1) face (also referred to as the C-face).

The growth thickness of the SiC grown single crystal is preferably 1 mm or greater, more preferably 2 mm or greater, even more preferably 3 mm or greater, yet more preferably 4 mm or greater and even yet more preferably 5 mm or greater. By carrying out crystal growth so as to have a concave crystal growth plane, it is possible to more easily obtain a SiC single crystal containing no inclusions throughout the entire range of the aforementioned thickness.

The diameter of the SiC grown single crystal having a concave crystal growth plane is preferably 3 mm or greater, more preferably 6 mm or greater, even more preferably 10 mm or greater and yet more preferably 15 mm or greater. By carrying out crystal growth so as to have a concave crystal growth plane, it is possible to more easily obtain a SiC single crystal containing no inclusions throughout the entire range of the aforementioned diameter.

A SiC single crystal having a thickness and/or diameter exceeding the aforementioned thickness and/or diameter may be grown, and more preferably it contains no inclusions even in the crystalline region exceeding the aforementioned thickness and/or diameter. However, the invention does not exclude a SiC single crystal containing inclusions in the crystalline region exceeding the aforementioned thickness and/or diameter, so long as the SiC single crystal obtained has no inclusions throughout the region having the aforementioned thickness and/or diameter. Thus, the maximum angle θ of the slope of the concave crystal growth plane may be measured, for example, as the angle with respect to the just plane 16 at a location where the desired diameter is obtained in the crystal growth plane 20.

In order to grow the crystal growth plane in a concave manner, it is effective to cause the Si—C solution to flow from the center section toward the outer peripheral section directly below the crystal growth plane, while increasing the degree of supersaturation of the Si—C solution at the outer peripheral section directly below the crystal growth plane to be greater than the degree of supersaturation of the Si—C solution at the center section directly below the crystal growth plane. This will allow the amount of crystal growth in the horizontal direction to be at a gradient for growth of the crystal growth plane in a concave manner, so that the crystal growth plane as a whole will not be on the just plane.

By creating a flow of the Si—C solution from the center section to the outer peripheral section directly below the crystal growth plane, pooling of the Si—C solution is minimized, and it is possible to stably supply solute to the entire crystal growth plane including the outer peripheral section while supplying solute to the center section that has slower growth of the concave crystal growth plane so that a SiC single crystal having a concave crystal growth plane containing no inclusions can be obtained.

The method for causing flow of the Si—C solution from the center section to the outer peripheral section directly below the crystal growth plane may be, as mentioned above, electromagnetic stirring with a high-frequency coil, rotation of the seed crystal substrate in contact with the Si—C solution, rotation of the crucible, or the like, and continuous rotation of the seed crystal substrate in one direction at a prescribed speed for a prescribed period of time or longer is preferred for creating a more stable flow of the Si—C solution.

By rotating the seed crystal substrate continuously in one direction at a prescribed speed for a prescribed period of time or longer, flow of the Si—C solution directly below the crystal growth plane is further promoted, stagnated flow sections of the Si—C solution at the outer peripheral sections can be eliminated and incorporation of solution at the outer peripheral sections (inclusions) can be more stably prevented.

The rotational speed of the seed crystal substrate is the speed at the outermost periphery of the growth surface (bottom face) of the seed crystal substrate (also referred to as the outer peripheral section or outermost periphery of the seed crystal substrate). The speed at the outer peripheral section of the seed crystal substrate is preferably greater than 25 mm/sec, more preferably at least 45 mm/sec and even more preferably at least 63 mm/sec. Limiting the speed at the outer peripheral section of the seed crystal substrate to within the aforementioned range will make it even easier to prevent inclusions.

When the speed at the outer peripheral section of the seed crystal substrate is controlled to grow a SiC single crystal, the grown crystal will usually grow so as to have the same diameter or an enlarged diameter with respect to the growth surface of the seed crystal substrate. Therefore the rotational speed at the outer peripheral section of the grown crystal will be the same as or greater than the speed at the outer peripheral section of the seed crystal substrate. Thus, controlling the speed at the outer peripheral section of the seed crystal substrate to within the aforementioned range allows flow of the Si—C solution to continue directly below the grown crystal even when crystal growth has proceeded.

The speed at the outer peripheral section of the grown crystal may be controlled to within the aforementioned speed range, instead of controlling the speed at the outer peripheral section of the seed crystal substrate. As growth of the SiC single crystal proceeds, the grown crystal generally grows in a manner such that its diameter is the same or an enlarged diameter with respect to the growth surface of the seed crystal substrate, resulting in an increasing speed at the outer peripheral section of the grown crystal. In that case, the rotational speed per minute (rpm) may be maintained, or the rotational speed per minute (rpm) may be reduced so that the speed at the outer peripheral section of the grown crystal is constant.

When both the seed crystal substrate and the crucible are to be rotated, the crucible may be rotated together with the seed crystal substrate in a range that allows the aforementioned rotational speed of the outer peripheral section of the seed crystal substrate to be achieved relative to the Si—C solution flowing by rotation of the crucible.

When the rotational direction of the seed crystal substrate is periodically switched, setting the time of rotation of the seed crystal substrate in the same direction (the rotation holding time) to be longer than a prescribed time period can stabilize the solution flow and more stably minimize incorporation of the solution into the outer peripheral sections.

By periodically changing the rotational direction of the seed crystal substrate, it is possible to grow a concentric SiC single crystal, and to minimize generation of defects that may be generated in the grown crystal. In that case, by keeping rotation in the same direction for a prescribed period of time or longer, it is possible to further stabilize flow of the Si—C solution directly below the crystal growth plane.

When the rotational direction of the seed crystal substrate is periodically changed, the rotation holding time in the same direction is preferably longer than 30 seconds, more preferably 200 seconds or longer and even more preferably 360 seconds or longer. Limiting the rotation holding time in the same direction of the seed crystal substrate to within the aforementioned range will make it even easier to minimize inclusions.

When the rotational direction of the seed crystal substrate is periodically changed, a shorter time for the stopping time of the seed crystal substrate during switching of the rotational direction in the reverse direction is desired, and it is preferably no greater than 10 seconds, more preferably no greater than 5 seconds, even more preferably no greater than 1 second and yet more preferably substantially 0 seconds.

In order to increase the degree of supersaturation of the Si—C solution at the outer peripheral section to above the degree of supersaturation of the Si—C solution at the center section, it is preferred to lower the temperature of the Si—C solution at the outer peripheral section directly below the crystal growth plane to be lower than the temperature of the Si—C solution at the center section directly below the crystal growth plane.

By lowering the temperature of the Si—C solution at the outer peripheral section to be lower than the temperature of the Si—C solution at the center section directly below the crystal growth plane, it is possible to increase the degree of supersaturation of the Si—C solution at the outer peripheral section to above the degree of supersaturation of the Si—C solution at the center section. By thus forming a gradient for the degree of supersaturation in the horizontal direction within the Si—C solution directly below the crystal growth plane, a SiC crystal can be grown having a concave crystal growth plane. This allows crystal growth without the crystal growth plane of the SiC single crystal being on the just plane, and can further minimize generation of inclusions. The temperature of the Si—C solution and the temperature of the grown crystal are substantially the same at the interface of crystal growth, and control of the temperature of the Si—C solution directly below the crystal growth plane is substantially the same as control of the temperature on the grown crystal surface.

The method for forming a temperature gradient in which the temperature of the Si—C solution is lower at the outer peripheral section than at the center section directly below the crystal growth plane may be a meniscus growth method wherein crystal growth is carried out while forming a meniscus between the seed crystal substrate and the Si—C solution, a heat loss control method using a seed crystal holding shaft with higher thermal conductivity at the side sections than at the center section, or a method in which gas is blown from the outer peripheral side of the grown crystal.

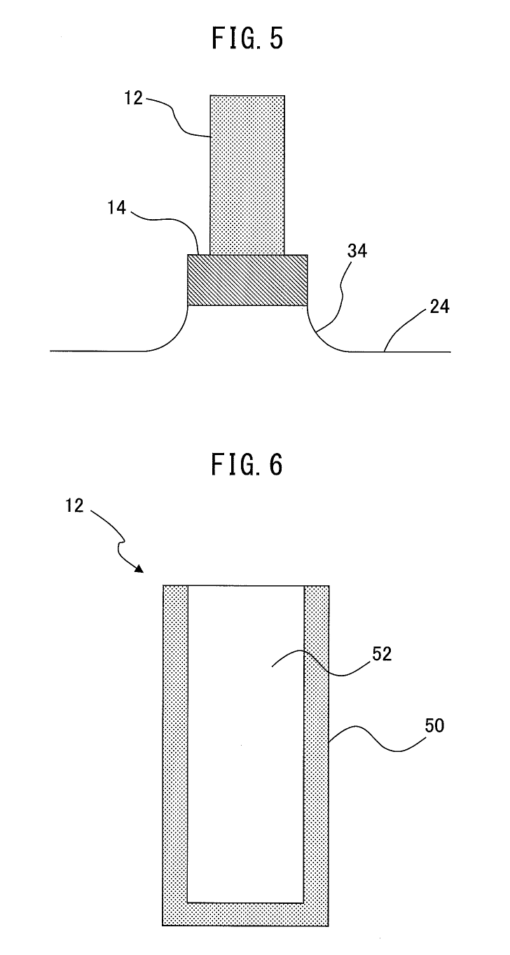

The term “meniscus” refers to a concave curved surface formed on the surface of the Si—C solution raised by surface tension upon wetting of the seed crystal substrate, as shown in FIG. 5. A meniscus growth method is a method in which the SiC single crystal is grown while forming a meniscus between the seed crystal substrate and the Si—C solution. To form a meniscus, for example, after the seed crystal substrate has been contacted with the Si—C solution, the seed crystal substrate may be raised and held at a position where the bottom face of the seed crystal substrate is higher than the liquid level of the Si—C solution.

Since the meniscus portion formed on the outer peripheral section of the growth interface is at a lower temperature due to radiation heat loss, formation of the meniscus can create a temperature gradient in which the temperature of the Si—C solution is lower at the outer peripheral section than at the center section directly below the crystal growth plane. This can increase the degree of supersaturation of the Si—C solution at the outer peripheral section directly below the growth surface, so that it is greater than the degree of supersaturation of the Si—C solution at the center section directly below the growth surface.

A seed crystal holding shaft having a constitution in which the side sections exhibit higher thermal conductivity than the center section may be used instead of a commonly used graphite shaft as described above. By using a seed crystal holding shaft wherein the thermal conductivity differs at the side sections and the center section, it is possible to control the degree of heat loss through the seed crystal holding shaft in the direction of the diameter of the seed crystal holding shaft.

A seed crystal holding shaft having a constitution in which the side sections exhibit higher thermal conductivity than the center section may have a constitution as shown in FIG. 6, where the thermal conductivity at the side sections 50 is higher than the thermal conductivity at the center section 52. By using a seed crystal holding shaft having such a constitution, it is possible to vary the degree of heat loss through the seed crystal holding shaft in the direction of the diameter of the seed crystal holding shaft, and to promote heat loss more at the outer peripheral sections than at the center section of the Si—C solution directly below the grown crystal surface. Therefore, the temperature of the Si—C solution at the outer peripheral sections directly below the crystal growth plane may be lower than the temperature of the Si—C solution at the center section directly below the crystal growth plane, and the degree of supersaturation of the Si—C solution at the outer peripheral sections directly below the crystal growth plane may be greater than the degree of supersaturation of the Si—C solution at the center section directly below the crystal growth plane.

The seed crystal holding shaft having a different thermal conductivity at the side sections 50 and the center section 52, shown in FIG. 6, may also be hollow at the center section 52. A hollow construction at the center section 52 can lower the thermal conductivity of the center section 52 with respect to the thermal conductivity at the side sections 50.

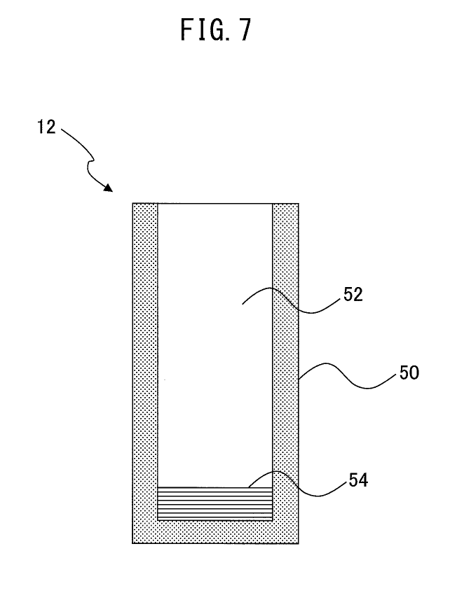

When the center section 52 has a hollow construction, two or more heat-insulating materials may be situated in at least part of the hollow part. For example, as shown in FIG. 7, a heat-insulating material 54 may be placed at the bottom part of the center section 52, to further increase the difference in thermal conductivity between the side sections 50 and the center section 52 of the seed crystal holding shaft 12. The heat-insulating material 54 may occupy the entire center section 52. The two or more heat-insulating materials may be made of the same material and/or have the same shape, or they may be made of different materials and/or have different shapes.

The heat-insulating material used may be a graphite-based heat-insulating material, carbon fiber-molded heat-insulating material, or anisotropic heat-insulating material, such as pyrolytic graphite (PG). When an anisotropic heat-insulating material is used, since the anisotropic heat-insulating material has anisotropic thermal conductivity, the anisotropic heat-insulating material may be disposed at an orientation such that heat conduction is inhibited in the axial direction of the seed crystal holding shaft and heat conduction is promoted in the direction of the diameter of the seed crystal holding shaft.

A seed crystal holding shaft having a constitution in which the side sections exhibit higher thermal conductivity than the center section may have a constitution in which the thermal conductivity at the center section is preferably ½ to 1/20 and more preferably ⅕ to 1/10 with respect to the thermal conductivity of the side section.

The seed crystal holding shaft 12 may be constructed of a material such that the material composing the center section 52 has lower thermal conductivity than the material composing the side section 50, or alternatively, it may have a constitution in which at least parts of the side sections 50 and center section 52 of the seed crystal holding shaft differ in thermal conductivity in a range allowing heat loss to proceed further at the outer peripheral sections than at the center section of the Si—C solution directly below the grown crystal plane.

The seed crystal substrate that can be used for one embodiment of the present disclosure may be, for example, a SiC single crystal that has been normally grown by a sublimation process. It is preferred to use a SiC single crystal having a flat growth surface and having a (0001) just plane or (000-1) just plane, or a SiC single crystal having a concave growth surface and having a (0001) face or (000-1) face at a section near the center section of the concave growth surface. The overall shape of the seed crystal substrate may be any desired shape, such as plate-like, discoid, cylindrical, columnar, truncated conic or truncated pyramidal.

The method of examining inclusions is not particularly restricted, and as shown in FIG. 4(a), the grown crystal 40 may be sliced parallel to the growth direction to cut a grown crystal 42 as shown in FIG. 4(b), and observation may be made of whether or not the entire surface of the grown crystal 42 is a continuous crystal based on a transmission image, to allow examination of the presence of inclusions. When the grown crystal 40 is grown in a substantially concentrical manner, it may be further cut in half at the center section of the cut out grown crystal 42, and the presence of inclusions in the half-cut grown crystal 42 may be examined by the same method. The grown crystal may also be sliced perpendicular to the growth direction, and the presence of inclusions in the cut grown crystal may be examined by the same method. Also, the grown crystal may be cut out as described above and subjected to energy dispersive X-ray spectroscopy (EDX) or wavelength dispersive X-ray analysis (WDX) for qualitative analysis or quantitative analysis of the Si—C solution component in the cut out grown crystal, to allow detection of inclusions.

With observation of the transmission image, since visible light is not transmitted at the sections where inclusions are present, the sections where visible light is not transmitted may be detected as inclusions. According to elemental analysis by EDX or WDX, when a Si/Cr-based solvent is used as the Si—C solution, for example, it is analyzed whether solvent components other than Si and C, such as Cr, are present in the grown crystal, and the solvent components other than Si and C, such as Cr, can be detected as inclusions.

In some embodiments, meltback may be carried out in which the surface layer of the seed crystal substrate is dissolved in the Si—C solution and removed prior to growth of a SiC single crystal. Since the surface layer of the seed crystal substrate on which the SiC single crystal is grown may have an affected layer, such as a dislocation, a natural oxide film, or the like, removal of these by dissolution prior to growth of a SiC single crystal is effective for growing a high-quality SiC single crystal. Although the thickness of a layer to be dissolved depends on processed conditions of the surface of a seed crystal substrate, it is preferably about 5 to 50 μm for sufficient removal of an affected layer or a natural oxide film.

The meltback may be carried out by forming in the Si—C solution a temperature gradient in which the temperature increases from the interior of the Si—C solution toward the surface of the solution, i.e. by forming a temperature gradient in a direction opposite to the case of SiC single crystal growth. The temperature gradient in the opposite direction can be formed by controlling the output of the high-frequency coil.

In some embodiments, the seed crystal substrate may be preheated in advance, and then the same is contacted with the Si—C solution. If the seed crystal substrate at a low temperature is contacted with the Si—C solution at high temperature, heat shock dislocation may be generated in the seed crystal. Preheating of the seed crystal substrate before contacting the seed crystal substrate with the Si—C solution prevents heat shock dislocation and is effective for growth of a high-quality SiC single crystal. The seed crystal substrate may be heated together with the seed crystal holding shaft. In that case, heating of the seed crystal holding shaft is stopped after contact of the seed crystal substrate with the Si—C solution and before growth of the SiC single crystal. Alternatively, the Si—C solution may be heated to the temperature for crystal growth after contacting the seed crystal with the Si—C solution at a relatively low temperature. This is also effective for preventing heat shock dislocations and growing a high-quality SiC single crystal.

### EXAMPLES

### Simulation of Flow Direction and Temperature Gradient of Si—C Solution

The flow direction and the temperature gradient of a Si—C solution during growth of a SiC single crystal by a solution process (Flux method) were simulated using CGSim (Simulation software of bulk crystal growth from solution, STR Japan, Ver.14.1).

The simulation conditions were set to the following standard conditions.

### (Construction of Standard Model)

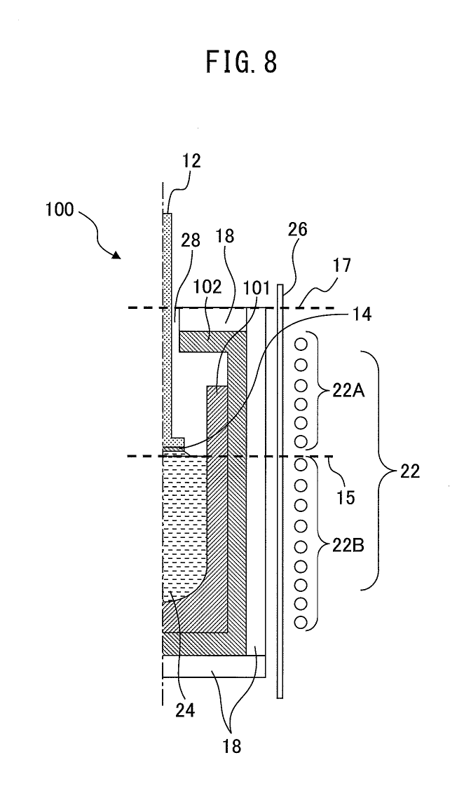

As a single crystal production apparatus there was prepared a symmetrical model of the construction of the single crystal production apparatus 100 shown in FIG. 8. The seed crystal holding shaft 12 used was a graphite shaft comprising a disc with a thickness of 2 mm and a diameter of 25 mm at the tip of a circular column with a diameter of 9 mm and a length of 180 mm. The seed crystal substrate 14 used was a discoid 4H-SiC single crystal with a thickness of 1 mm and a diameter of 25 mm.

The top face of the seed crystal substrate 14 was held at the center section of the end face of the seed crystal holding shaft 12. The seed crystal holding shaft 12 and seed crystal substrate 14 were positioned so that the seed crystal holding shaft 12 passed through an opening 28 with a diameter of 20 mm at the top section of a graphite heat-insulating material 18 with a thickness of 15 mm and a graphite outer crucible 102 with a thickness of 5 mm. The gap between the outer crucible 102 and the seed crystal holding shaft 12 at the opening 28 and the gap between the heat-insulating material 18 and the seed crystal holding shaft 12 at the opening 28 were each 5.5 mm.

Molten Si was placed in a graphite inner crucible 101 having a round inside bottom section, with a thickness of 10 mm for the side section and the lowermost section, an inner diameter of 70 mm, and a height (length in the vertical direction from the inside lowermost section to the top end) of 80 mm, in a region up to 40 mm from the lowermost section of the inner crucible 101. The atmosphere inside the single crystal production apparatus was helium. Around the side section of the outer crucible 102, there were situated high-frequency coils 22 consisting of an upper level coil 22A and a lower level coil 22B, each capable of independent output control. The upper level coil 22A comprised a 5-coil high-frequency coil, and the lower level coil 22B comprised a 10-coil high-frequency coil. The coils were lined in a row in the vertical direction at a location 16 mm from the side section of the outer crucible 102 in the horizontal direction, being evenly arranged in a region from the location 54.5 mm to the location 223.5 mm (33.5 mm from the uppermost section of the outer peripheral surface of the outer crucible 102 in the vertical upward direction) from the lowermost section of the outer peripheral surface of the outer crucible 102 in the vertical upward direction.

The seed crystal substrate 14 held on the seed crystal holding shaft was positioned so that the bottom face of the seed crystal substrate 14 was located 1.5 mm above the location of the liquid level of the Si—C solution 24, and a meniscus was formed as shown in FIG. 5, so that the Si—C solution wetted the entire bottom face of the seed crystal substrate 14. The diameter of the meniscus portion of the liquid level of the Si—C solution 24 was 30 mm, and the shape of the meniscus between the liquid level of the Si—C solution 24 and the bottom face of the seed crystal substrate 14 was rectilinear for simplification of the calculation.

The location in the vertical direction that is maximally heated, when a carbon material (graphite) as the heated section is situated adjacent to the high-frequency coil, is represented by a dashed line, as the center section 15 of the high-frequency coil. At the start of crystal growth (initial settings), the center section 15 of the high-frequency coil is the same location as the liquid level of the Si—C solution 24. The top end of the heat-insulating material 18 at the start of crystal growth (initial settings) is represented as a dashed line, as the hot zone top end 17.

The other simulation conditions were as follows.

Calculation using 2D symmetrical model:

Power of upper level coil 22A=0; Frequency of lower level coil 22B=5 kHz;

Temperature at surface of Si—C solution 24=2000° C.;

Rotation of seed crystal holding shaft and seed crystal substrate=0 rpm; Rotation of outer crucible and inner crucible=5 rpm;

The physical properties of the materials were as follows.

Inner crucible 101, outer crucible 102 and seed crystal holding shaft 12: Graphite materials, thermal conductivity at 2000° C.=17 W/(m·K), emission ratio=0.9;

Heat-insulating material 18: Graphite material, thermal conductivity at 2500° C.=1.2 W/(m·K), emission ratio=0.8;

Si—C solution: Molten Si, thermal conductivity at 2000° C.=66.5 W/(m·K), emission ratio=0.9; density=2600 kg/m³, electric conductivity=2,245,000 S/m;

He: Thermal conductivity at 2000° C.=0.579 W/(m·K);

Temperature of water-cooling chamber and high-frequency coil=300K.

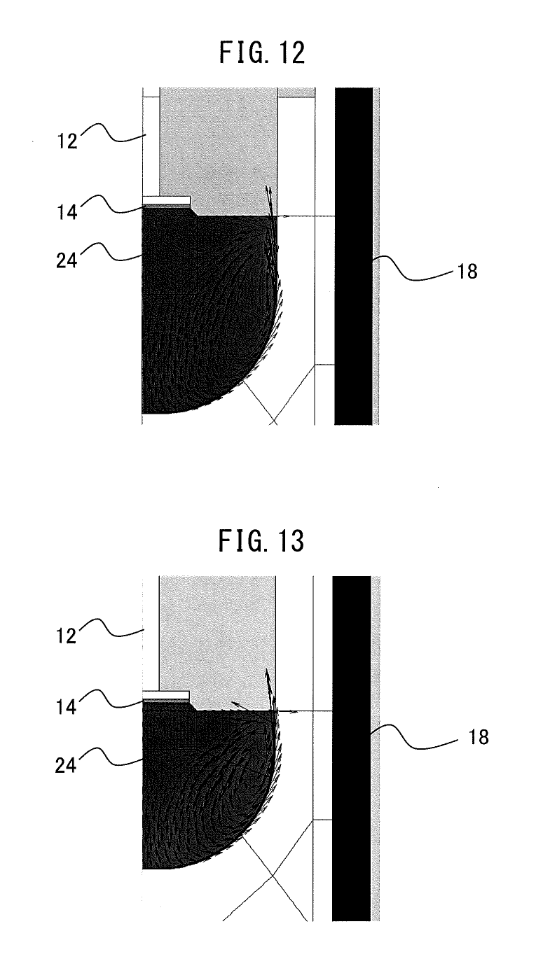

Simulation of the flow direction and the temperature gradient of the Si—C solution was carried out under the above conditions. FIG. 12 shows the results of a simulation of the state of flow of a Si—C solution directly below the crystal growth plane, where flow of the Si—C solution has stabilized. When there was no change in liquid level height of the Si—C solution before growth of the SiC single crystal, i.e. when the flow of the Si—C solution at the start of the crystal growth was a stable state, the upward flow speed of the Si—C solution 5 mm below the growth surface of the seed crystal substrate was 28 mm/sec, and the average temperature gradient of the Si—C solution in a range of 1 cm in the direction vertically below the growth surface of the seed crystal substrate was 20° C./cm.

### Example 1

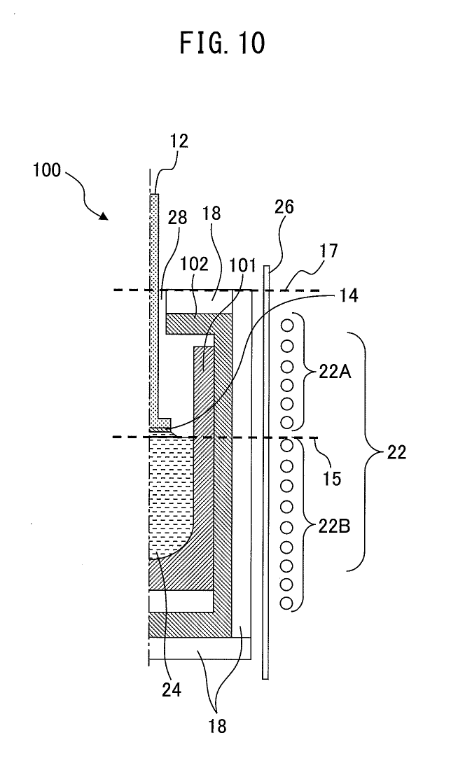

Assuming that the liquid level of the Si—C solution falls as crystal growth of the SiC single crystal proceeds, another model was prepared against the above standard model, wherein the liquid level of the Si—C solution was 10 mm lower in the vertical downward direction. Also, a model was prepared in which growth of the SiC single crystal was carried out while moving only the inner crucible 101 by 10 mm in the vertical upward direction without moving the outer crucible 102 and the heat-insulating material 18, as shown in FIG. 10, so that positional shifting between the liquid level of the Si—C solution and the center section of the high-frequency coil was eliminated. Thus, the liquid level of the Si—C solution was at the same position as the center section 15 of the high-frequency coil at the start of crystal growth (initial settings), and the top end of the heat-insulating material 18 was at the same position as the hot zone top end 17 at the start of crystal growth (initial settings).

FIG. 13 shows the results of a simulation of the state of flow of a Si—C solution directly below the crystal growth plane, where flow of the Si—C solution has stabilized, under the aforementioned conditions of Example 1. The upward flow speed of the Si—C solution 5 mm below the growth surface of the seed crystal substrate was 31 mm/sec, and the average temperature gradient of the Si—C solution in a range of 1 cm in the direction vertically below the growth surface of the seed crystal substrate was 23° C.

### Reference Example 1

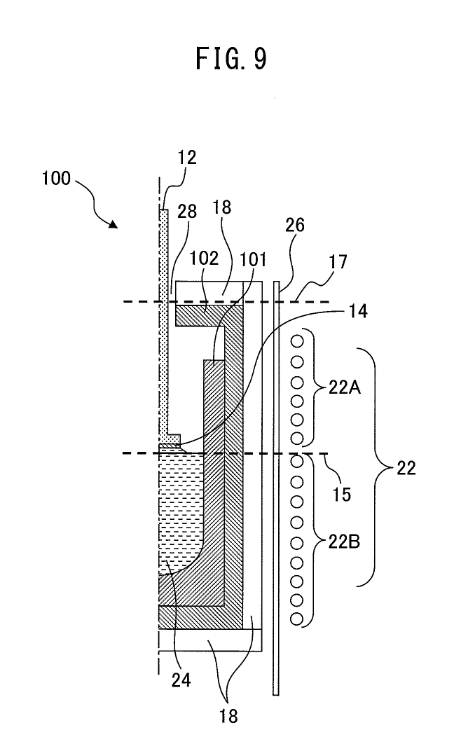

A simulation was carried out under the same conditions as Example 1, except that the entire heated section (hot zone) including the inner crucible 101, outer crucible 102 and heat-insulating material 18 was moved 10 mm in the vertical upward direction to maintain the positional relationship between the liquid level of the Si—C solution and the center section of the high-frequency coil, as shown in FIG. 9. Thus, the liquid level of the Si—C solution was at the same position as the center section 15 of the high-frequency coil at the start of crystal growth (initial settings), but the top end of the heat-insulating material 18 had shifted 10 mm in the vertical upward direction from the hot zone top end 17 at the start of crystal growth (initial settings).

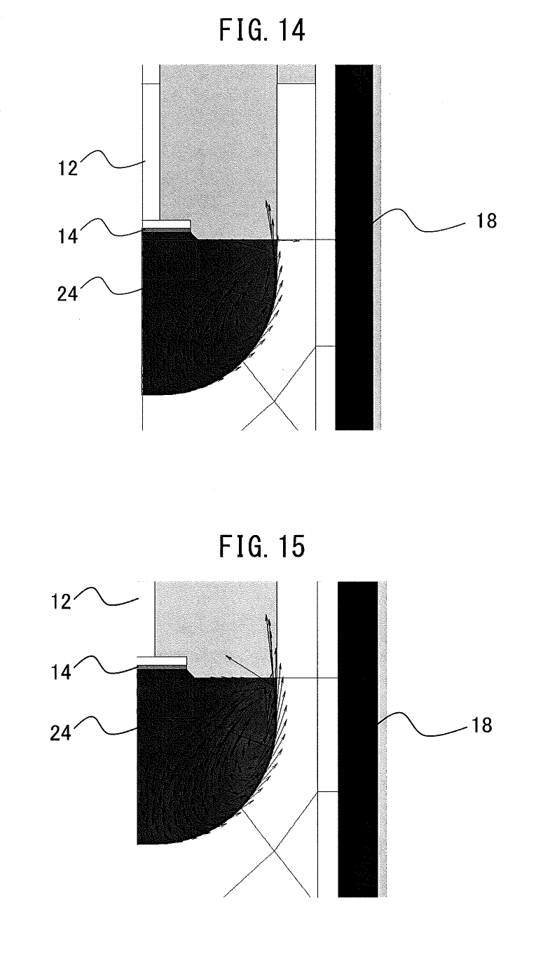

FIG. 14 shows the results of a simulation of the state of flow of a Si—C solution directly below the crystal growth plane, where flow of the Si—C solution has stabilized, under the aforementioned conditions of Reference Example 1. The upward flow speed of the Si—C solution at a location 5 mm below the growth surface of the seed crystal substrate was 31 mm/sec, and the average temperature gradient of the Si—C solution in a range of 1 cm in the direction vertically below the growth surface of the seed crystal substrate was 33° C./cm.

### Comparative Example 1

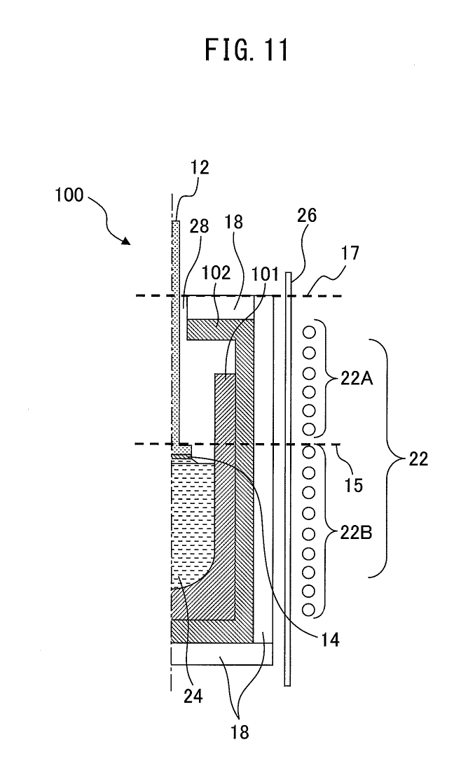

A simulation was carried out under the same conditions as Example 1, except that neither the inner crucible 101, outer crucible 102 nor heat-insulating material 18 was moved, as shown in FIG. 11. Thus, the liquid level of the Si—C solution was at a location 10 mm lower than the center section 15 of the high-frequency coil at the start of crystal growth (initial settings), while the top end of the heat-insulating material 18 was at the same position as the hot zone top end 17 at the start of crystal growth (initial settings).

FIG. 15 shows the results of a simulation of the state of flow of a Si—C solution directly below the growth surface, where flow of the Si—C solution has stabilized under the aforementioned conditions of Comparative Example 1. The upward flow speed of the Si—C solution at a location 5 mm below the growth surface of the seed crystal substrate was 38 mm/sec, and the average temperature gradient of the Si—C solution in a range of 1 cm in the direction vertically below the growth surface of the seed crystal substrate was 16° C./cm.

Table 1 shows the upward flow speed of the Si—C solution at a location 5 mm directly below the crystal growth plane of the seed crystal substrate and the average temperature gradient of the Si—C solution within 1 cm from the growth surface of the seed crystal substrate in the vertical downward direction, at the start of crystal growth (initial settings), as obtained in Example 1, Reference Example 1 and Comparative Example 1.

TABLE 1

| | Upward flow | | | |
|---|---|---|---|---|
| | speed | Change in | Average | Change in |
| | of Si—C | upward | temperature | temperature |
| | solution | flow speed | gradient | gradient |
| | (mm/s) | (%) | (° C./cm) | (%) |
| Start of | 28 | — | 20 | — |
| crystal growth | | | | |
| Example 1 | 31 | +10.7% | 23 | +15% |
| Ref. Example 1 | 31 | +10.7% | 33 | +65% |
| Comp. Example 1 | 38 | +35.7% | 16 | −20% |

In Example 1, the increase in upward flow speed of the Si—C solution was reduced compared to Reference Example 1 and Comparative Example 1, and the change in temperature gradient was also reduced. This shows that generation of inclusions is reduced, allowing more homogeneous growth of a SiC single crystal.

### EXPLANATION OF SYMBOLS

100 Single crystal production apparatus
200 Single crystal production apparatus
10 Crucible
101 Inner crucible
102 Outer crucible
12 Seed crystal holding shaft
14 Seed crystal substrate
16 Just plane of seed crystal substrate
18 Heat-insulating material
20 Concave crystal growth plane
22 High-frequency coil
22A Upper level high-frequency coil
22B Lower level high-frequency coil
24 Si—C solution
26 Quartz tube
28 Opening at top of crucible
34 Meniscus
40 SiC grown crystal
42 Cut grown crystal
50 Side section of seed crystal holding shaft
52 Center section of seed crystal holding shaft
54 Heat-insulating material disposed at center section of seed crystal holding shaft

What is claimed is:

1. A method for producing a SiC single crystal by a solution process, comprising contacting a seed crystal substrate held on a seed crystal holding shaft with a Si—C solution to conduct crystal growth of a SiC single crystal, the Si—C solution being housed in a crucible and having a temperature gradient in which the temperature decreases from the interior toward the surface,
wherein a high-frequency coil is disposed around the side sections of the crucible, and
the crucible has a multilayer structure including an inner crucible, and one or more outer crucibles disposed surrounding the inner crucible, and
wherein the method comprises moving the inner crucible alone in the vertical upward direction so as to minimize changes in the relative position of the liquid level of the Si—C solution and the center section of the high-frequency coil in the vertical direction during the crystal growth of the SiC single crystal.
